(19) United States
(12) Patent Application Publication
(10) Pub. No.: US 2026/0291537 A1
(43) Pub. Date: Sep. 24, 2026

(54) BROADBAND POWER COMBINER/SPLITTER WITH REDUCED IMPEDANCE

(71) Applicant: BAE Systems Information and Electronic Systems Integration Inc., Nashua, NH (US)

(72) Inventor: Nick Yang, Chelmsford, MA (US)

(73) Assignee: BAE Systems Information and Electronic Systems Integration Inc., Nashua, NH (US)

(21) Appl. No.: 19/085,982

(22) Filed: Mar. 20, 2025

(51) Int. Cl. H04B 1/40; H03F 3/24

(52) U.S. Cl. CPC H04B 1/40; H03F 3/245

(57) ABSTRACT

Receiver, transmitter, or transceiver system employing a broadband power combiner/splitter with reduced impedance. An example system implementing the techniques includes a power combiner/splitter circuit having a first port, a second port, and a third port. The first port is coupled to the second port through a first transmission line and to the third port through a second transmission line. An isolation resistance is coupled between the second port and the third port and is configured based on a desired low terminal impedance for the power combiner/splitter (e.g., less than 30 ohms). A power amplifier may be coupled to the first port of the power combiner/splitter and configured to provide a terminal impedance to match the terminal impedance of the power combiner/splitter. A first antenna may be coupled to the second port of the power combiner/splitter and a second antenna may be coupled to the third port of the power combiner/splitter.

### FIELD OF DISCLOSURE

The present disclosure relates to communications, and more particularly to a broadband power combiner/splitter with reduced impedance.

### BACKGROUND

Power combiners/splitters can be used in a number of applications, such as radar systems and communications systems. For example, systems that receive and/or transmit broadband signals (e.g., frequencies extending into the tens of Gigahertz and higher) typically need to combine and/or split such signals. Power combiner/splitter circuits can induce signal degradation, for example, in the form of insertion loss and return loss, at higher frequencies which can adversely impact the performance of the system.

### BRIEF DESCRIPTION OF THE DRAWINGS

FIG. 1 is a block diagram of a transceiver showing both receive and transmit applications, configured in accordance with certain embodiments of the present disclosure.

FIG. 2 is a block diagram of a power splitter/combiner that can be used in receive and/or transmit applications such as shown in FIG. 1, configured in accordance with certain embodiments of the present disclosure.

FIG. 3 is a block diagram of a broadband power splitter/combiner that can be used in receive and/or transmit applications such as shown in FIG. 1, configured in accordance with certain embodiments of the present disclosure.

FIG. 4 is a block diagram of another transceiver showing both receive and transmit applications, configured in accordance with certain embodiments of the present disclosure.

FIG. 5 is a flowchart illustrating a methodology for fabrication of a receiver, transmitter, or transceiver, in accordance with an embodiment of the present disclosure.

Although the following Detailed Description will proceed with reference being made to illustrative embodiments, many alternatives, modifications, and variations thereof will be apparent in light of this disclosure.

### DETAILED DESCRIPTION

Techniques are provided herein for a broadband power combiner/splitter with reduced impedance. The combiner/splitter can be used in any number of applications, but is particularly useful in communications systems, such as receiver systems, transmitter systems, or transceiver systems. As noted above, broadband transceiver systems typically employ power combiner/splitter circuits to combine and split broad band signals (e.g., frequencies extending into the tens of Gigahertz and higher) between antennas, amplifiers, and other components. These power combiner/splitter circuits can induce signal degradation at higher frequencies, for example in the form of insertion loss and return loss, which can adversely impact the performance of the system.

To this end, and in accordance with an embodiment of the present disclosure, a broadband power combiner/splitter circuit configured for reduced impedance is described. The combiner/splitter circuit may be used, for instance, to minimize phase difference between the combining/splitting ports of the circuit, which improves high frequency response. The reduced impedance may be achieved through the selection of an isolation resistor of relatively low value and reduced length, as described below. In addition to improving high frequency response of a given transceiver system (or other communications systems, such as a broadband receiver or transmitter), the lower resistance value and reduced length of the isolation resistor may also provide improved thermal performance.

In some examples, the power combiner/splitter with reduced impedance can be matched with a low impedance power amplifier and low impedance antennas to form a transceiver system. For applications where higher impedance antennas are needed, an impedance transformer may be deployed between the splitter/combiner circuit and the antennas.

In accordance with an embodiment, a receiver system implementing the techniques for reduced impedance includes a power combiner comprising a first input port, a second input port, an output port coupled to the first input port through a first transmission line and coupled to the second input port through a second transmission line, and an isolation resistor coupled between the first input port and the second input port. The isolation resistor is configured based on a desired terminal impedance (e.g., impedance measured at the ports) for the power combiner of less than 30 ohms. The power combiner is configured to combine a first signal provided at the first input port with a second signal provided at the second input port, to generate a combined signal. The system may also include a first antenna coupled to the first input port of the power combiner and configured to receive the first signal. The system may further include a second antenna coupled to the second input port of the power combiner and configured to receive the second signal. The system may further include a power amplifier configured to amplify the combined signal. The power amplifier is coupled to the output port of the power combiner and configured to provide a terminal input impedance to match the terminal impedance of the power combiner.

In accordance with an embodiment, a transmitter system implementing the techniques for reduced impedance includes a power splitter comprising a first output port, a second output port, an input port coupled to the first output port through a first transmission line and coupled to the second output port through a second transmission line, and an isolation resistor coupled between the first output port and the second output port. The isolation resistor is configured to provide a desired terminal impedance for the power splitter of less than 30 ohms. The power splitter is configured to split an input signal provided at the input port to generate a first output signal and a second output signal. The system may also include a first antenna coupled to the first output port of the power splitter and configured to transmit the first output signal. The system may further include a second antenna coupled to the second output port of the power splitter and configured to transmit the second output signal. The system may further include a power amplifier configured to generate the input signal to the power splitter as an amplification of a signal to be transmitted. The power amplifier is coupled to the input port of the power splitter and configured to provide a terminal output impedance to match the terminal impedance of the power splitter.

In yet another example embodiment, a transceiver includes both receive and transmit circuitry along with a power combiner/splitter which may be coupled to the transmit and receive circuits. The power combiner/splitter circuit includes a first port, a second port, and a third port. The first port is coupled to the second port through a first transmission line and to the third port through a second transmission line. An isolation resistor is coupled between the second port and the third port and is configured to provide isolation for a low terminal impedance power combiner/splitter (e.g., less than 30 ohms). A power amplifier may be coupled to the first port of the power combiner/splitter and configured to provide a terminal impedance to match the terminal impedance of the power combiner/splitter. A first antenna may be coupled to the second port of the power combiner/splitter and a second antenna may be coupled to the third port of the power combiner/splitter

It will be appreciated that the techniques described herein may provide improved transceiver performance at higher frequencies, compared to other systems that utilize higher impedance combiner/splitters. Numerous embodiments and applications will be apparent in light of this disclosure.

### System Architecture

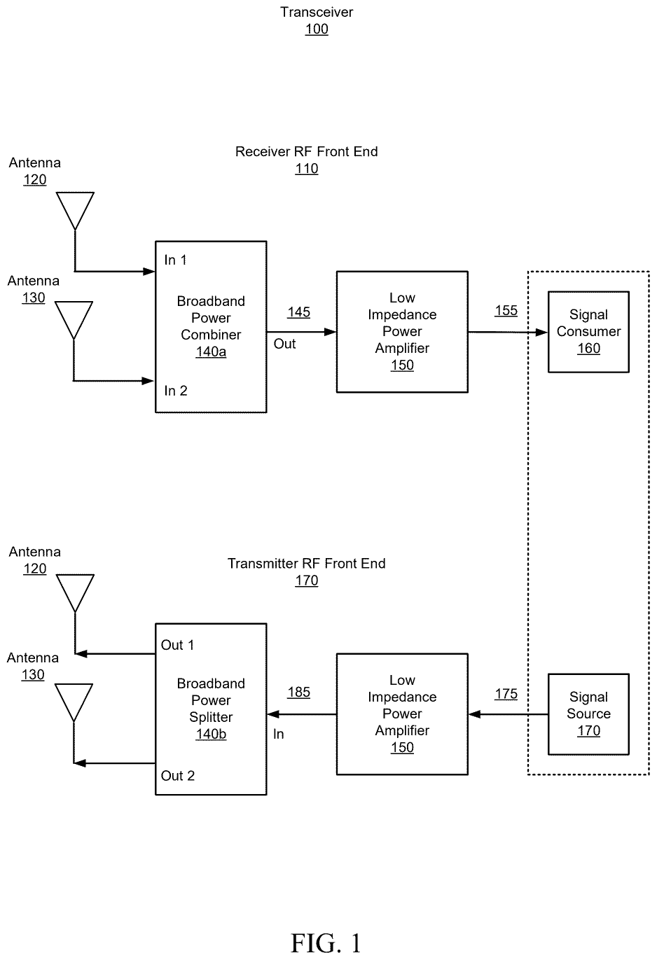

FIG. 1 is a block diagram of a transceiver 100, configured in accordance with certain embodiments of the present disclosure. The transceiver 100 is shown to include a receiver RF front end 110 (or receiver for short), configured to provide received signals to a signal consumer 160, and a transmitter RF front end 170 (or transmitter for short)), configured to provide signals from a signal source 170 to be transmitted. As shown, the receiver and transmitter applications may share some components in common but are depicted separately to better show the signal processing direction.

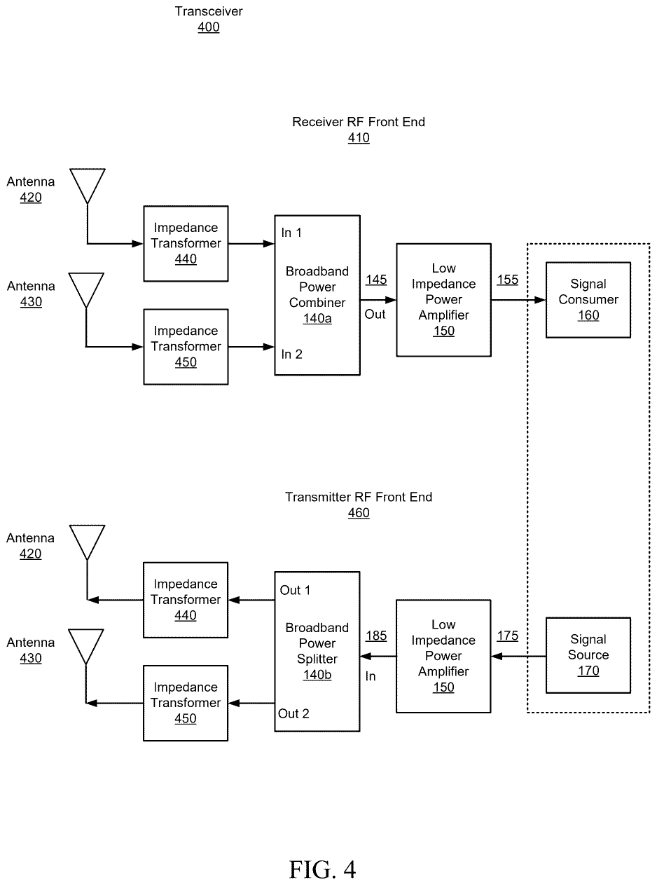

The receiver 110 is shown to include antennas 120 and 130, broadband power combiner 140a, low input impedance power amplifier 150, and a signal consuming circuit 160. Although broadband antennas typically have high input impedance (e.g., 75 ohms or more), that case will be described below in connection with FIG. 4. The antennas 120 and 130 of this example are low input impedance antennas (e.g., less than 30 ohms) configured to receive signals that have been transmitted from one or more emitting sources. The broadband power combiner 140a is configured to combine the signals received from antenna 120 and antenna 130, at the input ports, into a combined signal 145 at the output port. The broadband power combiner 140a is configured with reduced terminal impedance (e.g., less than 30 ohms) which, along with a reduced isolation resistor value, can minimize phase difference between the input ports coupled to the antennas. The reduced phase difference improves the high frequency response of the receiver, as will be described below. The low input impedance power amplifier 150 is configured to amplify the combined signal 145 to generate an amplified signal 155. The amplified signal 155 may then be provided to a signal consuming circuit or application 160 that is configured to analyze or otherwise act on that signal. The signal consuming circuit or application 160 may further process (e.g., filter) amplified signal 155 and apply that signal to one or more further circuits. The signal consuming circuit or application 160 may be configured for any application (e.g., radar systems, tracking systems, targeting systems, communications systems).

The transmitter 170 operates in a similar manner to the receiver, except that the signal direction is reversed, and is shown to include antennas 120 and 130, broadband power splitter 140b, low output impedance power amplifier 150, and a signal source circuit 170. A signal source circuit 170 is configured to generate a signal 175 that is to be transmitted. Just as the signal consuming circuit or application 160, the signal source circuit 170 may be configured for any application (e.g., radar systems, tracking systems, targeting systems, communications systems). In an example, each of signal consuming circuit or application 160 and signal source circuit 170 are part of the same backend system. The signal 175 is provided to the low output impedance power amplifier 150 which is configured to generate an amplified signal 185. The low terminal impedance provided by the broadband power splitter 140b reduces overlap of the voltage and current waveforms at the amplifier output which results in improved power density and efficiency of the amplifier.

The broadband power splitter 140b is configured to split the amplified signal 185, provided at the input port, into two signals that can then be provided to antenna 120 and antenna 130, at the output ports, for transmission. The broadband power splitter 140b is configured with reduced terminal impedance (e.g., less than 30 ohms) which, along with a reduced isolation resistor value, can minimize phase difference between the output ports coupled to the antennas and provide impedance matching with the power amplifier 150. The reduced phase difference improves the high frequency response of the transmitter. For example, in a radar system the signal may be a pulse train (e.g., a sequence of square waves) that are made up of odd harmonics. The resulting high bandwidth of the power splitter 140b is able to support the multiple odd harmonics that form the radar pulse train signal.

In some embodiments, and just as shown with respect to antennas 120, 130 and power amplifier 150, the broadband power splitter 140b may be the same circuit as the broadband power combiner 140a, except that the input and output ports may be reversed depending on signal propagation direction. For example, when used as a combiner (receive direction), the ports coupled to the antennas are input ports and the port coupled to the power amplifier is an output port. Conversely, when used as a splitter (transmit direction), the port coupled to the power amplifier is an input port and the ports coupled to the antennas are output ports. In this manner, the principles of reciprocity may apply, and the transmit and receive paths may each have the same componentry from antennas 120, 120 to power amplifier 150, with power amplifier 150 being coupled to both signal consuming circuit or application 160 and signal source circuit 170. The antennas 120, 130 and the power amplifier 150 may be configured to be relatively low impedance (e.g., less than 30 ohms) to match the reduced terminal impedance of the broadband power splitter/combiner circuit 140. In some embodiments the impedance of the antennas, broadband power splitter/combiner circuit, and power amplifier are in the range of 1 to 30 ohms.

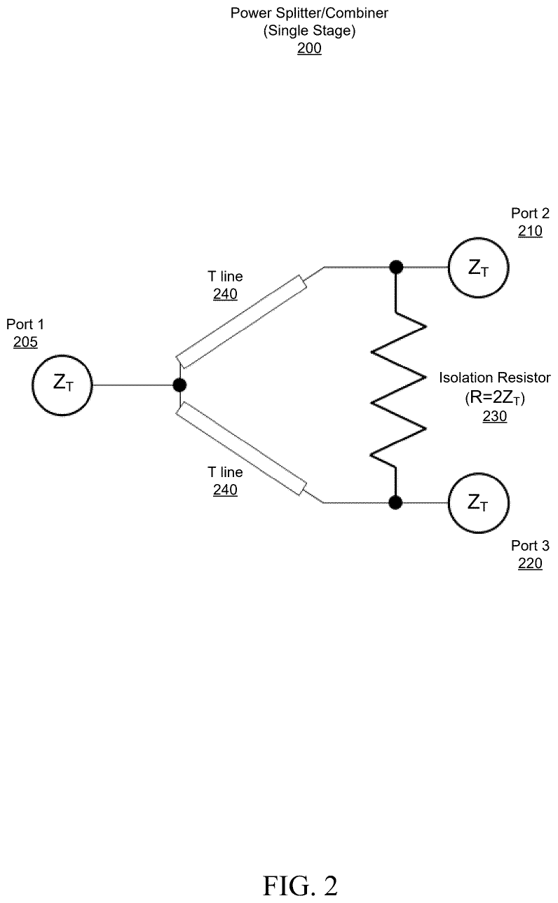

FIG. 2 is a block diagram of a single stage power splitter/combiner circuit 200, configured in accordance with certain embodiments of the present disclosure. The power splitter/combiner 200 in this example is configured as a single stage splitter/combiner which is not necessarily broadband but serves as a baseline example of a splitter/combiner that can serve as one of the stages of the multi-stage splitter/combiner, described below. The power splitter/combiner 200 is shown to include three ports 205, 210, and 220, transmission lines 240, and an isolation resistor 230. When functioning as a power combiner, the circuit 200 receives input signals at port 2 (210) and port 3 (220) and combines them into an output signal to be provided at port 1 (205). When functioning as a power splitter, the circuit 200 receives an input signal at port 1 (205) and splits that signal into two output signals to be provided at port 2 (210) and port 3 (220).

One of the transmission lines 240 is employed to couple port 1 to port 2, and the other transmission line is employed to couple port 1 to port 3. The transmission lines are configured to be of a length that is one quarter of the wavelength associated with the frequency of the signal of interest to be received or transmitted.

The isolation resistor R 230 is coupled between port 2 and port 3 and is configured to isolate port 2 from port 3 and is based on a desired terminal impedance Z_{T} of the power splitter/combiner 200. In some embodiments, the value of R may be set to 2Z_{T} to achieve that desired impedance Z_{T}. In some embodiments, the terminal impedance may be equal to the characteristic or reference impedance of the power splitter/combiner 200. The desired terminal impedance may be chosen to provide impedance matching such that the terminal impedance of the power splitter/combiner 200 matches (e.g., is equal to within a selected tolerance) the impedance of the circuits or devices that are connected to the ports 205, 210, 220. In some embodiments, the desired terminal impedance for the power combiner/splitter is less than 30 ohms.

At lower signal frequencies (e.g., longer wavelengths), the phase angle difference across the isolation resistor 230, between ports 2 and 3, is negligible. At higher signal frequencies, however, the shorter wavelength results in a more significant phase angle difference across the isolation resistor 230. This increased phase angle difference causes degraded performance at those higher frequencies. By decreasing the length of the isolation resistor 230, the phase angle difference across the resistor is reduced, and therefore the phase angle difference between the signal at ports 2 and 3 is reduced, thus improving high frequency performance. The reduction in the resistor length also lowers the resistance value of the isolation resistor 230 which is a result of decreasing the terminal impedance of the power splitter/combiner 200, creating a better match to power amplifiers and antennas having a lower terminal impedance. The lower resistance also improves the thermal handling characteristics of the power splitter combiner. The width and thickness of the isolation resistor may also be adjusted as needed to achieve a particular desired resistance value and to meet the power handling requirements of the circuit or system.

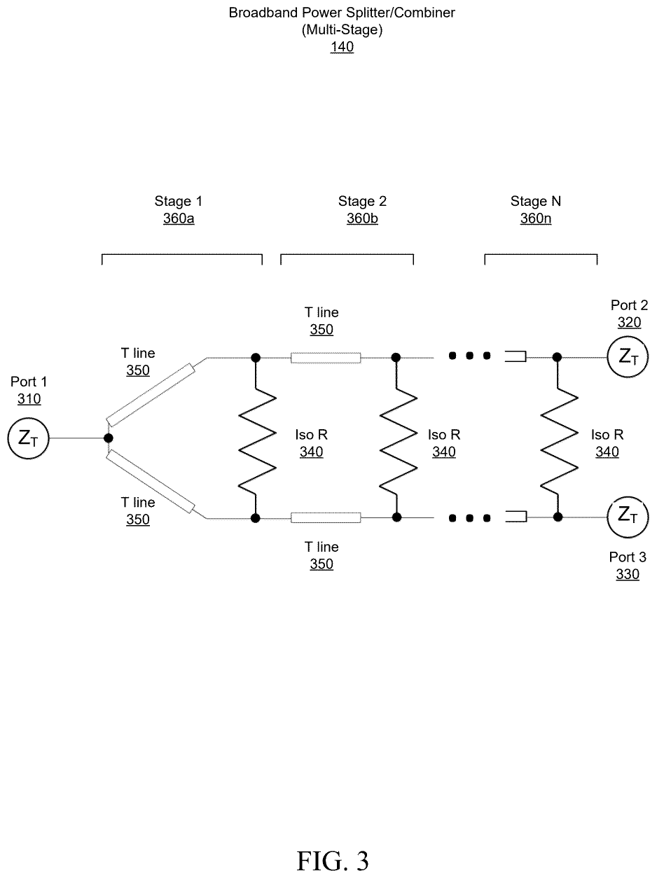

FIG. 3 is a block diagram of the broadband power splitter/combiner 140 of FIG. 1, configured in accordance with certain embodiments of the present disclosure. The broadband power splitter/combiner 140 in this example is configured as a multi-stage embodiment of the splitter/combiner 200 previously disclosed. The broadband power splitter/combiner 140 is shown to include two or more cascaded stages (e.g., stage 1 360a, stage 2 360b, . . . stage N 360n) that each comprise two transmission lines 350 and an isolation resistor 340 between the transmission lines of that stage. The number of stages to be employed may be selected based on a high frequency cutoff requirement for the splitter/combiner. For example, additional stages increase the bandwidth of the splitter/combiner The values of the isolation resistors increase with the number of cascaded stages. The isolation resistor values may be determined empirically or through simulation, based on the desired terminal impedance Z_{T} to be achieved by the splitter/combiner.

FIG. 4 is a block diagram of another transceiver 400, configured in accordance with certain embodiments of the present disclosure. The transceiver 400 is shown to include a receiver RF front end 410 (or receiver for short), configured to provide received signals to a signal consumer 160, and a transmitter RF front end 460 (or transmitter for short), configured to provide signals from a signal source 170 to be transmitted. The receiver 410 and transmitter 460 may share some components in common.

Transceiver 400 is similar to transceiver 100, as described above in connection with FIG. 1, with the addition of impedance transformers 440 and 450. The transceiver 400 in this embodiment, is configured for use with antennas 420 and 430 that are of higher impedance than antennas 120 and 130 of the transceiver 100 of FIG. 1. For example, antennas 420, 430 may be configured to be at a relatively high input impedance of 75 ohms or more. In this case impedance transformers 440 and 450 are used to provide impedance matching between the higher impedance antennas 420, 430 and the reduced impedance broadband power splitter/combiner 140. Impedance transformers 440 and 450 may be any suitable type of impedance transformer, such as, for example, a taper design transformer.

### Methodology

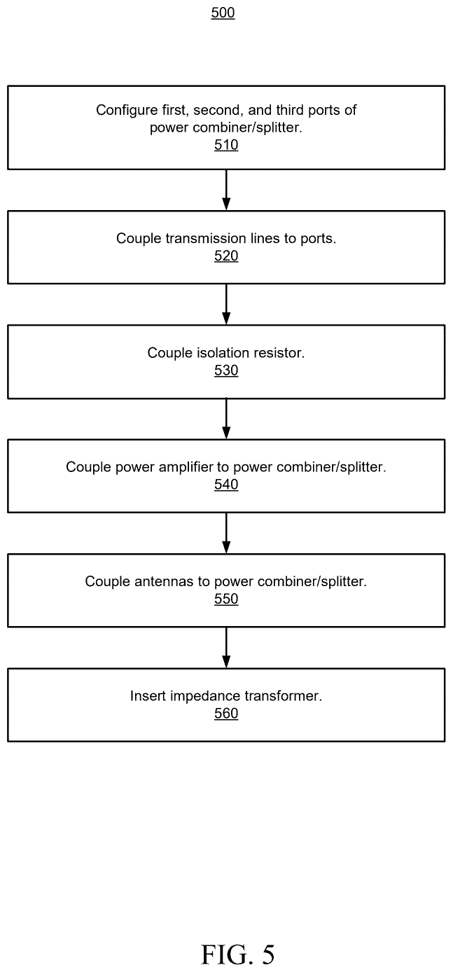

FIG. 5 is a flowchart illustrating a methodology 500 for fabrication of a transceiver, in accordance with an embodiment of the present disclosure. As can be seen, example method 500 includes a number of phases and sub-processes, the sequence of which may vary from one embodiment to another. However, when considered in aggregate, these phases and sub-processes form a process for fabrication of a transceiver, in accordance with an embodiment of the present disclosure, in accordance with certain of the embodiments disclosed herein, for example as illustrated in FIGS. 1-4, as described above. However other system architectures can be used in other embodiments, as will be apparent in light of this disclosure. To this end, the correlation of the various functions shown in FIG. 5 to the specific components illustrated in the figures, is not intended to imply any structural and/or use limitations. Rather other embodiments may include, for example, varying degrees of integration wherein multiple functionalities are effectively performed by one system. Numerous variations and alternative configurations will be apparent in light of this disclosure.

In one embodiment, method 500 commences, at operation 510, by configuring a power combiner/splitter circuit to include a first port, a second port, and a third port.

At operation 520, the first port is coupled to the second port through a first transmission line and the first port is coupled to the third port through a second transmission line.

At operation 530, an isolation resistor is coupled between the second port and the third port. In some embodiments, the isolation resistor is configured based on the desired terminal impedance for the power combiner/splitter, for example to match impedances of other components that are to be coupled to the power combiner/splitter such as an antenna and amplifier. In some embodiments, the desired terminal impedance of the power combiner/splitter is less than 30 ohms. In some embodiments, the value of the isolation resistor is twice the terminal impedance of the power combiner/splitter.

At operation 540, a power amplifier is coupled to the first port of the power combiner/splitter. The power amplifier is configured to provide a terminal impedance that matches the terminal impedance of the power combiner/splitter. In some embodiments, the terminal impedance of the power amplifier is less than 30 ohms.

At operation 550, a first antenna is coupled to the second port of the power combiner/splitter and a second antenna is coupled to the third port of the power combiner/splitter. In some embodiments, the input impedance of the first and/or second antennas may be configured to match the terminal impedance of the power combiner/splitter.

In some other embodiments, the input impedance of the first and/or second antennas may be configured to exceed the terminal impedance of the power combiner/splitter. For example, the input impedance of the antennas may exceed 75 ohms. In such case, at operation 560, an impedance transformer may be inserted between that antenna and the power combiner/splitter. The impedance transformer is configured to match the input impedance of the antenna to the terminal impedance of the power combiner/splitter.

In some embodiments, additional operations may be performed, as previously described in connection with the system. For example, the length of the first and second transmission lines may be set to one quarter of the wavelength associated with the frequency of the signals to be combined or split.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smartphones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood, however, that other embodiments may be practiced without these specific details, or otherwise with a different set of details. It will be further appreciated that the specific structural and functional details disclosed herein are representative of example embodiments and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

Example 1 is a receiver system comprising: a power combiner comprising a first input port, a second input port, an output port coupled to the first input port through a first transmission line and coupled to the second input port through a second transmission line, and an isolation resistor coupled between the first input port and the second input port, wherein a value of the isolation resistor is based on a terminal impedance for the power combiner of less than 30 ohms, wherein the power combiner is configured to combine a first signal provided at the first input port with a second signal provided at the second input port, to generate a combined signal; a first antenna coupled to the first input port of the power combiner and configured to receive the first signal; a second antenna coupled to the second input port of the power combiner and configured to receive the second signal; and a power amplifier coupled to the output port of the power combiner and configured to provide a terminal input impedance to match the terminal impedance of the power combiner, wherein the power amplifier is configured to amplify the combined signal.

Example 2 includes the system of Example 1, wherein an input impedance of the first antenna matches the terminal impedance of the power combiner, and an input impedance of the second antenna matches the terminal impedance of the power combiner.

Example 3 includes the system of Examples 1 or 2, wherein an input impedance of the first antenna exceeds the terminal impedance of the power combiner, and the system comprises an impedance transformer configured to match the input impedance of the first antenna to the terminal impedance of the power combiner.

Example 4 includes the system of any of Examples 1-3, wherein the input impedance of the first antenna exceeds 75 ohms.

Example 5 includes the system of any of Examples 1-4, wherein the terminal impedance of the power combiner is in a range of 1 ohm to 30 ohms and the terminal input impedance of the power amplifier is in a range of 1 ohm to 30 ohms.

Example 6 includes the system of any of Examples 1-5, wherein a value of the isolation resistor is twice the terminal impedance of the power combiner.

Example 7 includes the system of any of Examples 1-6, wherein a length of the first transmission line and a length of the second transmission line is equal to one quarter of a wavelength associated with a frequency of the first signal and/or the second signal.

Example 8 is a transmitter system comprising: a power splitter comprising a first output port, a second output port, an input port coupled to the first output port through a first transmission line and coupled to the second output port through a second transmission line, and an isolation resistor coupled between the first output port and the second output port, wherein a value of the isolation resistor is based on a terminal impedance for the power splitter of less than 30 ohms, wherein the power splitter is configured to split an input signal provided at the input port to generate a first output signal and a second output signal; a first antenna coupled to the first output port of the power splitter and configured to transmit the first output signal; a second antenna coupled to the second output port of the power splitter and configured to transmit the second output signal; and a power amplifier coupled to the input port of the power splitter and configured to provide a terminal output impedance to match the terminal impedance of the power splitter, wherein the power amplifier is configured to generate the input signal to the power splitter as an amplification of a signal to be transmitted.

Example 9 includes the system of Example 8, wherein an input impedance of the first antenna matches the terminal impedance of the power combiner, and an input impedance of the second antenna matches the terminal impedance of the power combiner.

Example 10 includes the system of Examples 8 or 9, wherein an input impedance of the first antenna exceeds the terminal impedance of the power combiner, and the system comprises an impedance transformer configured to match the input impedance of the first antenna to the terminal impedance of the power combiner.

Example 11 includes the system of Example 10, wherein the input impedance of the first antenna exceeds 75 ohms.

Example 12 includes the system of any of Examples 8-11, wherein the terminal impedance of the power combiner is in a range of 1 ohm to 30 ohms and the terminal output impedance of the power amplifier is in a range of 1 ohm to 30 ohms.

Example 13 includes the system of any of Examples 8-12, wherein a value of the isolation resistor is twice the terminal impedance of the power combiner.

Example 14 includes the system of any of Examples 8-13, wherein a length of the first transmission line and a length of the second transmission line is equal to one quarter of a wavelength associated with a frequency of the first output signal and/or the second output signal.

Example 15 is a method for fabrication of a transceiver, the method comprising: configuring a power combiner/splitter circuit to include a first port, a second port, and a third port; coupling the first port to the second port through a first transmission line; coupling the first port to the third port through a second transmission line; coupling an isolation resistor between the second port and the third port, wherein a value of the isolation resistor is based on a terminal impedance for the power combiner/splitter of less than 30 ohms; configuring a power amplifier to provide a terminal impedance to match the impedance of the power combiner/splitter; coupling the power amplifier to the first port of the power combiner/splitter; coupling a first antenna to the second port of the power combiner/splitter; and coupling a second antenna to the third port of the power combiner/splitter.

Example 16 includes the method of Example 15, comprising configuring an input impedance of the first antenna to match the terminal impedance of the power combiner/splitter, and configuring an input impedance of the second antenna to match the terminal impedance of the power combiner/splitter.

Example 17 includes the method of Examples 15 or 16, wherein an input impedance of the first antenna exceeds the terminal impedance of the power combiner/splitter, and the method comprises inserting an impedance transformer between the first antenna and the power combiner/splitter, the impedance transformer configured to match the input impedance of the first antenna to the terminal impedance of the power combiner/splitter.

Example 18 includes the method of Example 17, wherein the input impedance of the first antenna exceeds 75 ohms.

Example 19 includes the method of any of Examples 15-18, wherein the terminal impedance of the power combiner/splitter is in a range of 1 ohm to 30 ohms and the terminal impedance of the power amplifier is in a range of 1 ohm to 30 ohms.

Example 20 includes the method of any of Examples 15-19, wherein a value of the isolation resistor is twice the terminal impedance of the power combiner/splitter.

Example 21 is a power combiner comprising: a first input port; a second input port; an output port coupled to the first input port through a first transmission line and coupled to the second input port through a second transmission line; and an isolation resistor coupled between the first input port and the second input port, wherein a value of the isolation resistor is based on a terminal impedance for the power combiner of less than 30 ohms, wherein the power combiner is configured to combine a first signal provided at the first input port with a second signal provided at the second input port, to generate a combined signal.

Example 22 is a receiver circuit comprising the power combiner of Example 21.

Example 23 is a transmitter circuit comprising the power combiner of Example 21.

Example 24 is a transceiver circuit comprising the power combiner of Example 21.

Example 25 is a system comprising: the power combiner of claim 21, or the receiver circuit of claim 22, or the transmitter circuit of claim 23, or the transceiver circuit of claim 24; a first antenna coupled to the first input port of the power combiner and configured to receive the first signal; a second antenna coupled to the second input port of the power combiner and configured to receive the second signal; and a power amplifier coupled to the output port of the power combiner and configured to provide a terminal input impedance to match the terminal impedance of the power combiner, wherein the power amplifier is configured to amplify the combined signal.

Example 26 includes the system of Example 25, wherein an input impedance of the first antenna matches the terminal impedance of the power combiner, and an input impedance of the second antenna matches the terminal impedance of the power combiner.

Example 27 includes the system of Examples 25 or 26, wherein an input impedance of the first antenna exceeds the terminal impedance of the power combiner, and the system comprises an impedance transformer configured to match the input impedance of the first antenna to the terminal impedance of the power combiner.

Example 28 includes the system of Example 27, wherein the input impedance of the first antenna exceeds 75 ohms.

Example 29 includes the system of any of Examples 25-28, wherein the terminal impedance of the power combiner is in a range of 1 ohm to 30 ohms and the terminal input impedance of the power amplifier is in a range of 1 ohm to 30 ohms.

Example 30 includes the power combiner of Example 21, wherein a value of the isolation resistor is twice the terminal impedance of the power combiner.

Example 31 includes the power combiner of Example 21, wherein a length of the first transmission line and a length of the second transmission line is equal to one quarter of a wavelength associated with a frequency of the first signal and/or the second signal.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A receiver system comprising:
a power combiner comprising
a first input port,
a second input port,
an output port coupled to the first input port through a first transmission line and coupled to the second input port through a second transmission line, and
an isolation resistor coupled between the first input port and the second input port, wherein a value of the isolation resistor is based on a terminal impedance for the power combiner of less than 30 ohms,
wherein the power combiner is configured to combine a first signal provided at the first input port with a second signal provided at the second input port, to generate a combined signal;
a first antenna coupled to the first input port of the power combiner and configured to receive the first signal;
a second antenna coupled to the second input port of the power combiner and configured to receive the second signal; and
a power amplifier coupled to the output port of the power combiner and configured to provide a terminal input impedance to match the terminal impedance of the power combiner, wherein the power amplifier is configured to amplify the combined signal.

2. The system of claim 1, wherein an input impedance of the first antenna matches the terminal impedance of the power combiner, and an input impedance of the second antenna matches the terminal impedance of the power combiner.

3. The system of claim 1, wherein an input impedance of the first antenna exceeds the terminal impedance of the power combiner, and the system comprises an impedance transformer configured to match the input impedance of the first antenna to the terminal impedance of the power combiner.

4. The system of claim 3, wherein the input impedance of the first antenna exceeds 75 ohms.

5. The system of claim 1, wherein the terminal impedance of the power combiner is in a range of 1 ohm to 30 ohms and the terminal input impedance of the power amplifier is in a range of 1 ohm to 30 ohms.

6. The system of claim 1, wherein a value of the isolation resistor is twice the terminal impedance of the power combiner.

7. The system of claim 1, wherein a length of the first transmission line and a length of the second transmission line is equal to one quarter of a wavelength associated with a frequency of the first signal and/or the second signal.

8. A transmitter system comprising:
a power splitter comprising
a first output port,
a second output port,
an input port coupled to the first output port through a first transmission line and coupled to the second output port through a second transmission line, and
an isolation resistor coupled between the first output port and the second output port, wherein a value of the isolation resistor is based on a terminal impedance for the power splitter of less than 30 ohms,
wherein the power splitter is configured to split an input signal provided at the input port to generate a first output signal and a second output signal;
a first antenna coupled to the first output port of the power splitter and configured to transmit the first output signal;
a second antenna coupled to the second output port of the power splitter and configured to transmit the second output signal; and
a power amplifier coupled to the input port of the power splitter and configured to provide a terminal output impedance to match the terminal impedance of the power splitter, wherein the power amplifier is configured to generate the input signal to the power splitter as an amplification of a signal to be transmitted.

9. The system of claim 8, wherein an input impedance of the first antenna matches the terminal impedance of the power combiner, and an input impedance of the second antenna matches the terminal impedance of the power combiner.

10. The system of claim 8, wherein an input impedance of the first antenna exceeds the terminal impedance of the power combiner, and the system comprises an impedance transformer configured to match the input impedance of the first antenna to the terminal impedance of the power combiner.

11. The system of claim 10, wherein the input impedance of the first antenna exceeds 75 ohms.

12. The system of claim 8, wherein the terminal impedance of the power combiner is in a range of 1 ohm to 30 ohms and the terminal output impedance of the power amplifier is in a range of 1 ohm to 30 ohms.

13. The system of claim 8, wherein a value of the isolation resistor is twice the terminal impedance of the power combiner.

14. The system of claim 8, wherein a length of the first transmission line and a length of the second transmission line is equal to one quarter of a wavelength associated with a frequency of the first output signal and/or the second output signal.

15. A method for fabrication of a transceiver, the method comprising:
configuring a power combiner/splitter circuit to include a first port, a second port, and a third port;
coupling the first port to the second port through a first transmission line;
coupling the first port to the third port through a second transmission line;
coupling an isolation resistor between the second port and the third port, wherein a value of the isolation resistor is based on a terminal impedance for the power combiner/splitter of less than 30 ohms;
configuring a power amplifier to provide a terminal impedance to match the impedance of the power combiner/splitter;
coupling the power amplifier to the first port of the power combiner/splitter;
coupling a first antenna to the second port of the power combiner/splitter; and
coupling a second antenna to the third port of the power combiner/splitter.

16. The method of claim 15, comprising configuring an input impedance of the first antenna to match the terminal impedance of the power combiner/splitter, and configuring an input impedance of the second antenna to match the terminal impedance of the power combiner/splitter.

17. The method of claim 15, wherein an input impedance of the first antenna exceeds the terminal impedance of the power combiner/splitter, and the method comprises inserting an impedance transformer between the first antenna and the power combiner/splitter, the impedance transformer configured to match the input impedance of the first antenna to the terminal impedance of the power combiner/splitter.

18. The method of claim 17, wherein the input impedance of the first antenna exceeds 75 ohms.

19. The method of claim 15, wherein the terminal impedance of the power combiner/splitter is in a range of 1 ohm to 30 ohms and the terminal impedance of the power amplifier is in a range of 1 ohm to 30 ohms.

20. The method of claim 15, wherein a value of the isolation resistor is twice the terminal impedance of the power combiner/splitter.
